(19) United States
(12) Patent Application Publication
(10) Pub. No.: US 2026/0086600 A1
(43) Pub. Date: Mar. 26, 2026

(54) CIRCUIT FOR ASYNCHRONOUSLY AND SYNCHRONOUSLY CONVEYING TRIMMING BITS TO A REGISTER

(71) Applicant: STMicroelectronics International N.V., Geneva (CH)

(72) Inventors: Vikram SINGH, Radaur (IN); Ankur BAL, Greater Noida (IN); Anupam JAIN, New Delhi (IN)

(73) Assignee: STMicroelectronics International N.V., Geneva (CH)

(21) Appl. No.: 19/327,909

(22) Filed: Sep. 12, 2025

Related U.S. Application Data
(60) Provisional application No. 63/697,753, filed on Sep. 23, 2024.

(51) Int. Cl. G06F 1/14; H03K 3/037

(52) U.S. Cl. CPC G06F 1/14; H03K 3/037

(57) ABSTRACT

Provided is a circuit having a first input configured receive first data, a second input coupled configured to receive second data, a clock input configured to receive a clock signal during a first time period, the clock signal having a triggering edge during the first time period and an output. The circuit is configured to, before the first time period commences, output the first data over the output and in response to receiving the clock signal having the triggering edge during the first time period, output the second data over the output and refrain from outputting the first data.

### BACKGROUND

### Technical Field

The present disclosure is directed to a circuit for asynchronously and synchronously conveying trimming bits to a register.

### Description of the Related Art

Electronic devices, such as oscillators or regulators, have trimming bits that stored in one or more registers. It is desirable for the trimming bits to be controller-adjustable. As such, the controller may adjust the trimming bits to account for manufacturing imperfections, component specification mismatches or environmental conditions affecting the oscillator or regulator.

### BRIEF SUMMARY

Provided is a system for setting and adjusting an initial condition of a register, whereby the register may store trimming bits of a device, such as an oscillator. In the system, a controller has the flexibility to change the stored trimming bits using a register write interface and overwrite initial (or default) trimming bits. The initial trimming bits are stored in memory and are provided to the register asynchronously at reset or power up time, when a clock may not be available to synchronously write customized trimming bits.

The system includes a circuit, which may be a real time clock (RTC) controller circuit. The circuit selectively sends trimming bits to the register from one of two data paths. The circuit asynchronously (in a clock-free manner) conveys initial trimming bits that are stores in memory when a flip flop of the circuit is reset. Conversely, when the flip flop is clock edge-triggered, the circuit conveys trimming bits received over a line of an interface.

### BRIEF DESCRIPTION OF THE SEVERAL VIEWS OF THE DRAWINGS

FIG. 1 shows a system for setting and adjusting a programmable initial condition register.

FIG. 2 shows digital logic of the programmable initial condition register.

### DETAILED DESCRIPTION

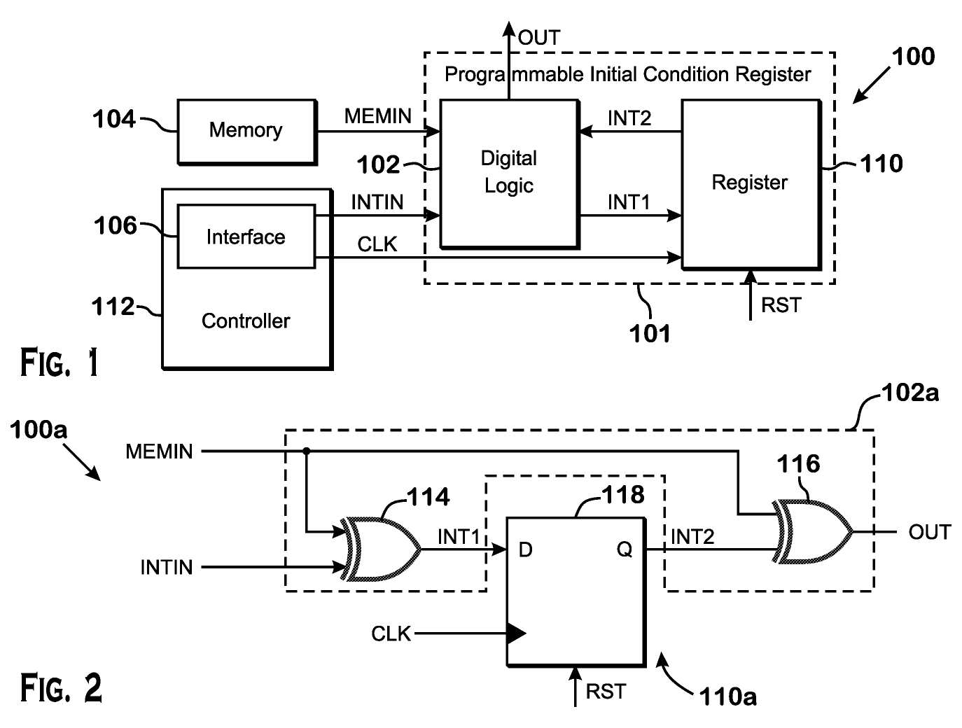

FIG. 1 shows a system 100 for setting and adjusting a programmable initial condition register 101. The system 100 includes the programmable initial condition register 101, which includes digital logic 102 and a register 110. The system 100 includes a memory 104 and a controller 112 having an interface 106. The memory 104 has an output (MEMIN). The interface 106 has two lines; data (INTIN) and a clock (CLK). The digital logic 102 has a first input coupled to the output of the memory 104, a second input coupled to a first line of the interface 106 and a third input coupled to a data output (INT2) of the register. The digital logic 102 has a first output configured (OUT) configured to output data and a second output coupled to a data input (INT1) of the register 110. In addition to the data input and data output, the register 110 has a first input coupled to the second line of the interface 106 and configured to receive the clock (CLK) and a second input configured to receive a reset signal (RST). The reset signal (RST) may provided by another controller (not shown), which may be a top level controller. The digital logic 102 may be a digital circuit and the register may be a flip flop as described herein.

The memory 104 may be non-volatile read-only memory (NVROM). The interface 106 may be any type of signal lines (e.g., data line or data bus with a clock) that provide data to the programmable initial condition register 101. For example, the interface 106 may be in accordance with the Inter-Integrated Circuit (I2C) protocol that allows a controller (such as the controller 112 or another controller) to send data (INTIN) to the programmable initial condition register 101, which may be a ‘peripheral’ per the I2C protocol. The interface 106 may have two lines; one for data or trimming bits (INTIN) and another for a clock signal (CLK). As described herein, a different controller may send a reset signal (RST) to the programmable initial condition register 101. The controller 112 may be a microcontroller, a microprocessor or a microcomputer. The controller 112 may be implemented by hardware, firmware, software, or their combination. An application specific integrated circuits (ASICs), digital signal processors (DSPs), digital signal processing devices (DSPDs), programmable logic devices (PLDs), and field programmable gate arrays (FPGAs), which are configured to perform the techniques described herein, may be provided in the controller 112.

The programmable initial condition register 101 may be a register for a device, such as an oscillator, such as a crystal oscillator, a digitally-controlled oscillator (DCO) or a resistance-capacitance (RC) oscillator, among others. The device may be a mixed-signal circuit that uses trimming bits. For example, the device may be a regulator, such as a voltage-controlled regulator. The register 110 may store trimming bits for the device. Even though one register is shown in FIG. 1, the device may have multiple registers, whereby each register may store one or more bits of the trimming bits. The device may retrieve the trimming bits from the register 110. The trimming bits may be used to set capacitance or resistance values of the device. For example, manufacturing imperfections, component specification mismatches and environmental conditions (such as, temperature) may cause a component of the device to have different properties than expected or to deviate from a specification. The trimming bits may be used to adjust the properties of the component. For example, during operation of the device, a calibration routine may be used to determine whether a component behavior (e.g., response) deviates from a specification of the component. If so, the trimming bits are set to adjust the behavior to be closer to the specification of the component.

The programmable initial condition register 101 may be provided with trimming bits at power up (or after reset). The trimming bits (MEMIN) may be programmable and may be stored in the memory 104. The digital logic 102 receives the trimming bits (MEMIN) from the memory 104 and passes them to the register 110 asynchronously (or in a clockless manner). The trimming bits may be adjusted some time later, where that time may be on the order of milliseconds. As described herein, the device may be an oscillator. At power up (or after reset to exit a low power mode), it may be desirable for initial trimming bits to be provided to the oscillator in an asynchronous or clockless manner even though the initial trimming bits are not optimal. Later on, when a phase lock loop (PLL) of the system is fully functional, the trimming bits may be adjusted by the controller 112 to more properly adjust the behavior of the oscillator.

The initial trimming bits may be determined during manufacturing. A frequency of the oscillator is compared to a desired frequency and a difference between the two is used to determine an adjustment. The initial trimming bits are set to provide the adjustment and are written to the memory 104.

At power up (or after reset), a top level controller may activate the reset signal (RST). Activating the reset signal (RST) may include sending a pulse or setting the reset signal (RST) to logical one. Upon being reset the programmable initial condition register 101 outputs the trimming bits received from the memory 104 over the first output (OUT) of the digital logic 102. Thereafter, the digital logic 102 receives trimming bits (INTIN) and the register 110 receives a clock signal (CLK) over the interface 106. Responsive to the clock signal (e.g., a rising or falling edge of the clock signal (CLK)), the programmable initial condition register 101 ceases outputting trimming bits (MEMIN) received from the memory 104 and instead outputs the trimming bits (INTIN) received over the interface 106.

FIG. 2 shows the programmable initial condition register 100a in accordance with an embodiment. The programmable initial condition register 100a includes the digital logic 102a and the register 110a, which is shown as a flip flop 118. The digital logic 102a includes first and second exclusive disjunction (XOR) gates 114, 116. The first exclusive disjunction gate 114 has a first input coupled to the output of the memory and over which the first exclusive disjunction gate 114 receives the initial trimming bits (MEMIN). The first exclusive disjunction gate 114 has a second input coupled to the first line of the interface 106 over which the digital logic 102a receives subsequent trimming bits (INTIN). The first exclusive disjunction gate 114 has an output (INT1). The flip flop 118 has a data input coupled to the output (INT1) of the first exclusive disjunction gate 114 and a clock input coupled to the second line of the interface 106 and over which the digital logic 102a receives the clock signal (CLK). The flip flop 118 has a reset input and over which the digital logic 102a receives the reset signal (RST). The flip flop 118 has an output (INT2). The second exclusive disjunction gate 116 has a first input coupled to the output of the memory and over which the second exclusive disjunction gate 116 receives the initial trimming bits (MEMIN). The second exclusive disjunction gate 116 has a second input coupled to the output (INT2) of the flip flop 118 and an output (OUT), which provides trimming bits to the device 108 (or register 110 thereof).

At power up (or after reset), the reset signal (RST) is activated (e.g., by the top level controller) to reset the flip flop 118. Accordingly, the flip flop 118 outputs logical zero to the second exclusive disjunction gate 116. Once reset (e.g., by the reset signal (RST) having a pulse or delta function), the flip flop 118 continues to output logical zero until the flip flop 118 is edge-triggered by the clock signal (CLK) at which time the flip flop 118 switches to outputting data received over its data input. When the second input of the second exclusive disjunction gate 116 is set to logical zero, the second exclusive disjunction gate 116 behaves as a buffer and outputs the data received over its first input. Accordingly, the programmable initial condition register 100a outputs the initial trimming bits (MEMIN) received from the memory. That is, the register 110a stores and outputs logical zero to the digital logic 102a. The digital logic 102a, using the second exclusive disjunction gate 116, passes the trimming bits stored in memory as the output of the programmable initial condition register 100a.

It is noted that the programmable initial condition register 100a may output one bit. In the event that the programmable initial condition register 100a is a multi-bit register or that there are multiple registers each having one or more bits, the digital logic 102a may be replicated for each bit of the registers. For example, in the event that eight trimming bits are used to allow for 256 different trimming settings, eight digital logic circuits may be used with each circuit servicing one of the bits.

After outputting the initial trimming bits (MEMIN), the controller may update register data with trimming bits received over the interface 106. Trimming bits are updated synchronously (with a clock signal). The controller 112 sends trimming bits (INTIN) over the first line of the interface 106 and the clock signal (CLK) over the second line of the interface 106. The trimming bits (INTIN) to be sent to the programmable initial condition register 100a may coincide with a triggering edge (rising edge) of the clock signal (CLK). It is noted that the flip flop 118 may alternatively be falling edge-triggered.

At the triggering edge of the clock signal (CLK), the flip flop 118 stores and outputs the data received over its data input. The digital logic 102a performs an exclusive disjunction on the initial trimming bits (MEMIN) and the trimming bits (INTIN) received over the interface 106 and causes the outcome of the exclusive disjunction to be stored in the flip flop 118. The second exclusive disjunction gate 116 receives the data stored in the flip flop 118. The second exclusive disjunction gate 116 performs an exclusive disjunction on the data stored in the flip flop 118 and the initial trimming bits (MEMIN).

That is, the second exclusive disjunction gate 116 performs an exclusive disjunction on the initial trimming bits (MEMIN) with the exclusive disjunction of the initial trimming bits (MEMIN) and the trimming bits (INTIN) received over the interface 106. The second exclusive disjunction gate 116 effectively outputs the trimming bits (INTIN) received over the interface 106 so long as the initial trimming bits (MEMIN) remain unchanged following the rising edge of the clock signal (CLK). The chain of the two exclusive disjunction gates 114, 116 each receiving the same input (of the initial trimming bits (MEMIN)) results in the gates 114, 116 each operating as a buffer for the trimming bits (INTIN) when the initial trimming bits (MEMIN) are logical zero and each operating as an inverter for the trimming bits (INTIN) when the initial trimming bits (MEMIN) are logical one. Thus, the digital logic 102a passes the received trimming bits (INTIN) as the output of the register 110a without altering their state when the flip flop 118 is clocked.

The digital logic 102a operates to output the initial trimming bits (MEMIN) when the flip flop 118 is reset. The flip flop 118 outputs logical zero (over INT2) when it is reset and blocks data received over its data input (INT1). Upon receiving logical zero over its second input, the second exclusive disjunction gate 116 operates as a buffer for the initial trimming bits (MEMIN) received over its first input outputs the initial trimming bits (MEMIN).

When the flip flop 118 receives a triggering edge of the clock signal (CLK), operation of the flip flop 118 is triggered. The flip flop 118 passes the output of the first exclusive disjunction gate 114 to the second exclusive disjunction gate 116. The two gates 114, 116 by virtue of having both received the initial trimming bits (MEMIN), collectively operate as two buffers or two inverters for the trimming bits (INTIN) received over the interface 106 and output the trimming bits (INTIN) received over the interface 106.

At power up and when a clock is not available, the digital logic 102a operates to provide the initial trimming bits (MEMIN) stored in the memory 104 and initialize the trimming bits. When a clock signal becomes available, the digital logic 102a provides a controller the ability to change or adjust the trimming bits. The digital logic 102a may be used to provide the initial trimming bits (MEMIN) and aid in initializing an oscillator when a reliable clock is unavailable (e.g., after exiting a power saving mode). The digital logic 102a offers the flexibility to write trimming bits that are received over an interface when a clock is available.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A system, comprising:
memory having an output and configured to output first data; and
a programmable initial condition register including:
a first input coupled to the output of the memory and configured receive the first data, and
a second input coupled to an interface and configured to receive second data over the interface,
a clock input configured to receive a clock signal during a first time period, the clock signal having a triggering edge during the first time period, and
an output,
wherein the digital logic is configured to:
before the first time period commences, output the first data over the output; and
in response to receiving the clock signal having the triggering edge during the first time period, output the second data over the output and refrain from outputting the first data.

2. The system of claim 1, wherein the programmable initial condition register has a reset input, and the programmable initial condition register is configured to:
receive a reset signal over the reset input; and
in response to the reset signal being activated, output the first data and cease outputting the second data until the triggering edge of the clock signal.

3. The system of claim 1, wherein the programmable initial condition register includes a flip flop, a first exclusive disjunction gate and a second exclusive disjunction gate.

4. The system of claim 3, wherein the flip flop is reset before the first time period commences to cause the second exclusive disjunction gate to output the first data and not the second data.

5. The system of claim 3, wherein in response to receiving the clock signal having the triggering edge during the first time period, the flip flop provides an output of the first exclusive disjunction gate as an input to the second exclusive disjunction gate.

6. The system of claim 5, wherein in response to receiving the clock signal having the triggering edge during the first time period, the first and second exclusive disjunction gates operate as two buffers for the second data when the first data is logical zero and operate as two inverters for the second data when the first data is logical one.

7. The system of claim 3, wherein
the first exclusive disjunction gate has:
a first input coupled to the first input of the programmable initial condition register,
a second input coupled to the second input of the programmable initial condition register, and
an output,
the flip flop has:
a data input coupled to the output of the first exclusive disjunction gate,
a clock input coupled to the clock input of the programmable initial condition register,
a reset input configured to receive a reset signal, and
a data output, and
the second exclusive disjunction gate has:
a first input coupled to the first input of the programmable initial condition register,
a second input coupled to the second input of the flip flop, and
an output coupled to the output of the programmable initial condition register.

8. A method, comprising:
receiving first data;
receiving an activated reset signal;
in response to the receiving the activated reset signal, outputting the first data;
receiving second data and a clock signal having a triggering edge during a first time period; and
in response to receiving the clock signal having the triggering edge during the first time period, outputting the second data and refraining from outputting the first data.

9. The method of claim 8, comprising:
determining, by a first exclusive disjunction gate, a first outcome of an exclusive disjunction of the first data and the second data; and
outputting, by the first exclusive disjunction gate, the first outcome of the exclusive disjunction to a flip flop.

10. The method of claim 9, comprising:
after receiving the activated reset signal and before receiving the clock signal having the triggering edge, outputting logical zero by the flip flop; and
after receiving the clock signal having the triggering edge, outputting, by the flip flop, the first outcome of the exclusive disjunction at the triggering edge of the clock signal.

11. The method of claim 10, comprising:
determining, by a second exclusive disjunction gate, a second outcome of the exclusive disjunction of the first data and an output of the flip flop; and
outputting, by the second exclusive disjunction gate, the second outcome of the exclusive disjunction.

12. The method of claim 11, wherein the second outcome of the exclusive disjunction is the first data when the flip flop outputs logical zero.

13. The method of claim 11, wherein the second outcome of the exclusive disjunction is the second data when the flip flop outputs the first outcome of the exclusive disjunction.

14. A circuit, comprising:
a first input configured receive first data;
a second input coupled configured to receive second data;
a clock input configured to receive a clock signal during a first time period, the clock signal having a triggering edge during the first time period; and
an output,
wherein the circuit is configured to:
before the first time period commences, output the first data over the output; and
in response to receiving the clock signal having the triggering edge during the first time period, output the second data over the output and refrain from outputting the first data.

15. The circuit of claim 14, comprising:
a reset input, wherein the circuit is configured to:
receive a reset signal over the reset input; and
in response to the reset signal being activated, output the first data and cease outputting the second data until the triggering edge of the clock signal.

16. The circuit of claim 14, comprising:
a flip flop;
a first exclusive disjunction gate; and
a second exclusive disjunction gate.

17. The circuit of claim 16, wherein the flip flop is reset before the first time period commences to cause the second exclusive disjunction gate to output the first data and not the second data.

18. The circuit of claim 16, wherein in response to receiving the clock signal having the triggering edge during the first time period, the flip flop provides an output of the first exclusive disjunction gate as an input to the second exclusive disjunction gate.

19. The circuit of claim 18, wherein in response to receiving the clock signal having the triggering edge during the first time period, the first and second exclusive disjunction gates operate as two buffers for the second data when the first data is logical zero and operate as two inverters for the second data when the first data is logical one.

20. The circuit of claim 16, wherein
the first exclusive disjunction gate has:
a first input coupled to the first input of the circuit,
a second input coupled to the second input of the circuit, and
an output,
the flip flop has:
a data input coupled to the output of the first exclusive disjunction gate,
a clock input coupled to the clock input of the circuit,
a reset input configured to receive a reset signal, and
a data output, and
the second exclusive disjunction gate has:
a first input coupled to the first input of the circuit,
a second input coupled to the second input of the flip flop, and
an output coupled to the output of the circuit.
